(19) United States
(12) Patent Application Publication
(10) Pub. No.: US 2011/0075383 A1
(43) Pub. Date: Mar. 31, 2011

(54) FIXING STRUCTURE

(75) Inventors: Chia-Ju Ho, Taipei City (TW); Cheng-Hsiung Yen, Taipei City (TW); Lao-Da Teng, Taipei City (TW)

(73) Assignee: INVENTEC CORPORATION, Taipei City (TW)

(21) Appl. No.: 12/627,296

(22) Filed: Nov. 30, 2009

(30) Foreign Application Priority Data
Sep. 30, 2009 (TW) 98133264

(51) Int. Cl. H05K 1/00

(52) U.S. Cl. 361/749; 361/748

(57) ABSTRACT

A fixing structure is adapted for an electronic device. The electronic device has a circuit board. The fixing structure includes a base plate and a position limiting element. The base plate has a first side and a second side. The position limiting element has a first limiting portion and a second limiting portion. The first limiting portion connects the first side of the base plate, and the second limiting portion connects the second side of the base plate, such that the position limiting element and the base plate together form a receiving space. The circuit board is adapted for passing through the receiving space, so as to be assembled onto the base plate.

### CROSS-REFERENCE TO RELATED APPLICATION

This application claims the priority benefit of Taiwan application serial no. 98133264, filed on Sep. 30, 2009. The entirety of the above-mentioned patent application is hereby incorporated by reference herein and made a part of specification.

### BACKGROUND OF THE INVENTION

1. Field of the Invention

The invention relates to a fixing structure. More particularly, the invention relates to a fixing structure applicable to an electronic device.

2. Description of Related Art

In current information era, human beings by degrees tend to rely on electronic products. The electronic products including mobile phones, computers, and video-audio equipment have become ubiquitous in our daily lives. Along with continual development of electronic technology, user-friendly electronic products with powerful functions have come forth and gradually replaced old electronic products. To smooth processes of assembling the electronic products, designs of various fixing structures become more and more significant.

FIG. 1 is a schematic partial view exemplarily illustrating a conventional notebook computer. As indicated in FIG. 1, to secure a circuit board 12 onto a main body 16 of the notebook computer 10, a piece of iron 14 is often required for fixing the circuit board 12 between the piece of iron 14 and the main body 16 by fastening the piece of iron 14 and the main body 16. Nonetheless, the piece of iron 14 occupies internal space of the notebook computer 10, and thereby the volume of the notebook computer 10 cannot be reduced.

On the other hand, other components are necessary for molding the piece of iron 14. Namely, the piece of iron 14 used for fixing the circuit board 12 is fabricated by performing an additional process according to the related art, thus necessitating extra costs, time, and efforts.

### SUMMARY OF THE INVENTION

The invention is directed to a fixing structure which can increase internal space of an electronic device and reduce manufacturing costs.

In the invention, a fixing structure adapted for an electronic device is provided. The electronic device has a circuit board. The fixing structure includes a base plate and a position limiting element. The base plate has a first side and a second side. The position limiting element has a first limiting portion and a second limiting portion. The first limiting portion connects the first side of the base plate, and the second limiting portion connects the second side of the base plate, such that the position limiting element and the base plate together form a receiving space. The circuit board is adapted for passing through the receiving space, so as to be assembled onto the base plate.

According to an exemplary embodiment of the invention, the circuit board is adapted for leaning against the first limiting portion and the second limiting portion, such that the circuit board is limited to be in the receiving space.

According to an exemplary embodiment of the invention, the position limiting element and the base plate are integrally formed.

According to an exemplary embodiment of the invention, a material of the position limiting element and the base plate is plastic.

According to an exemplary embodiment of the invention, the circuit board is a flexible printed circuit board (PCB).

According to an exemplary embodiment of the invention, the base plate further has a third side opposite to the first side, and the position limiting element further has a third limiting portion connecting the third side of the base plate.

According to an exemplary embodiment of the invention, the fixing structure further includes a positioning pin disposed on the base plate, and the circuit board has a positioning hole corresponding to the positioning pin.

Based on the above, the fixing structure of the invention serves to fasten the circuit board in no need of other components, which reduces costs and facilitates assembly. In addition, the space that the fixing structure occupies is rather small, and therefore the electronic device can have favorable space usage flexibility.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention.

FIG. 1 is a schematic view illustrating a conventional fixing structure.

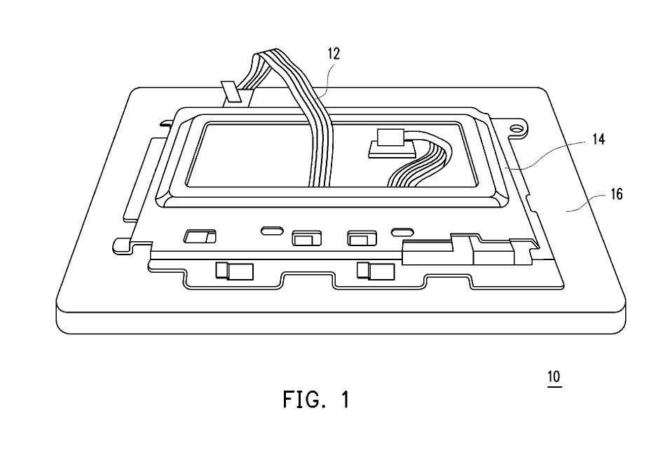

FIG. 2 is a partial top view illustrating an electronic device according to an exemplary embodiment of the invention.

FIG. 3 is a schematic view illustrating a fixing structure in the electronic device depicted in FIG. 2.

FIG. 4 is a schematic view illustrating the fixing structure depicted in FIG. 3 from another view angle.

### DESCRIPTION OF EMBODIMENTS

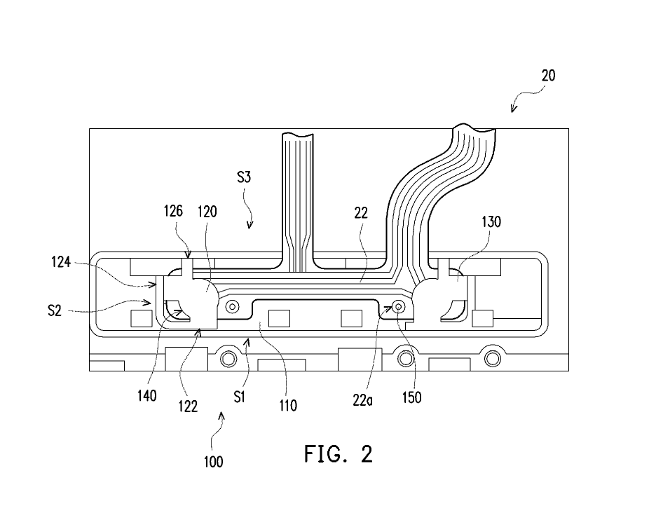

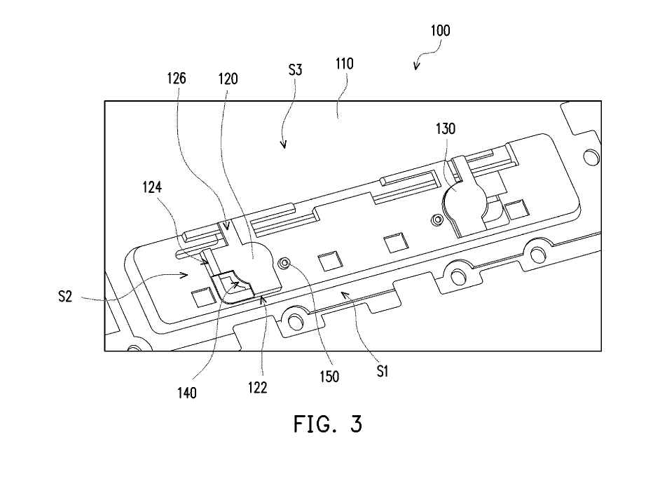

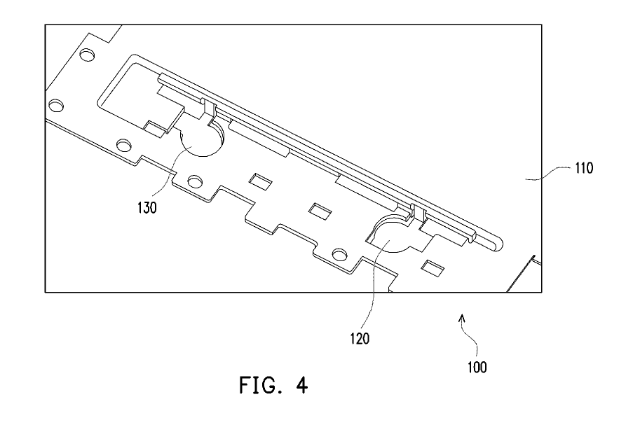

FIG. 2 is a partial top view illustrating an electronic device according to an exemplary embodiment of the invention. FIG. 3 is a schematic view illustrating a fixing structure in the electronic device depicted in FIG. 2. FIG. 4 is a schematic view illustrating the fixing structure depicted in FIG. 3 from another view angle. With reference to FIGS. 2˜4, the fixing structure 100 is adapted for an electronic device 20, and the electronic device 20 has a circuit board 22. In the embodiment, the electronic device 20 is a notebook computer, and the circuit board 22 is a flexible PCB disposed in a touch-sensing module (not shown) of the notebook computer.

According to the embodiment, the fixing structure 100 includes a base plate 110 and two position limiting elements 120 and 130. Structures and functions of the two position limiting elements 120 and 130 are identical, and therefore the position limiting element 120 is taken as an example to elaborate the invention as provided below.

The base plate 110 has a first side S1 and a second side S2. The position limiting element 120 has a first limiting portion 122 and a second limiting portion 124. The first limiting portion 122 connects the first side S1 of the base plate 110, and the second limiting portion 124 connects the second side S2 of the base plate 110, such that the position limiting element 120 and the base plate 110 together form a receiving space 140. Besides, the circuit board 22 is adapted for passing through the receiving space 140, so as to be assembled onto the base plate 110 and partially exposed by the position limiting element 120.

In the embodiment, a material of the position limiting element 120 and the base plate 110 can be plastic or another flexible material. Additionally, through applying an injection molding technology, the position limiting element 120 and the base plate 110 are integrally formed to simplify fabricating processes and reduce manufacturing costs.

With reference to FIG. 2 again, during assembly, a portion of the circuit board 22 passes through the receiving space 140 between the position limiting element 120 and the base plate 110 and is then assembled onto the base plate 110. Note that a side of the circuit board 22 can lean against the first limiting portion 122 and the second limiting portion 124 of the position limiting element 120, such that the circuit board 22 ceases to be pushed forward, and that the circuit board 22 can then perform a positioning function. Next, since the circuit board 22 is flexible, the other side of the circuit board 22 is embedded into the receiving space 140 between the position limiting element 130 and the base plate 110. Here, both sides of the circuit board 22 are limited by the two position limiting elements 120 and 130, such that the circuit board 22 is assembled onto the base plate 110.

Additionally, the base plate 110 has a third side S3 opposite to the first side S1, and the position limiting element 120 has a third limiting portion 126 connecting the third side S3 of the base plate 110. Thereby, structural connection strength between the position limiting element 120 and the base plate 110 can be enhanced, and the position limiting element 120 can be firmly fastened onto the base plate 110.

As shown in FIGS. 2 and 3, in the embodiment, the fixing structure 100 further includes two positioning pins 150, and the circuit board 22 has positioning holes 22a corresponding to the positioning pins 150. Through the positioning pins 150 and the positioning holes 22a, the circuit board 22 can be assembled onto the base plate 110 to a better extent.

In light of the foregoing, the fixing structure of the invention serves to fasten the circuit board in no need of other components, which reduces costs and facilitates assembly. Moreover, a side of the circuit board can lean against a first connecting portion and a second connecting portion where the position limiting element and the base plate are connected, such that the circuit board ceases to be pushed forward, and that the circuit board can perform the positioning function. In addition, the space that the fixing structure occupies is rather small, and therefore the electronic device can have favorable space usage flexibility.

Although the invention has been described with reference to the above embodiments, it will be apparent to one of ordinary skills in the art that modifications to the described embodiments may be made without departing from the spirit of the invention. Accordingly, the scope of the invention will be defined by the attached claims not by the above detailed descriptions.

What is claimed is:

1. A fixing structure adapted for an electronic device, the electronic device having a circuit board, the fixing structure comprising:
a base plate having a first side and a second side; and
a position limiting element disposed on the base plate, the position limiting element having a first limiting portion and a second limiting portion, wherein the first limiting portion connects the first side of the base plate, and the second limiting portion connects the second side of the base plate, such that the position limiting element and the base plate together form a receiving space, and that the circuit board is adapted for passing through the receiving space and is assembled onto the base plate.

2. The fixing structure as claimed in claim 1, wherein the circuit board is adapted for leaning against the first limiting portion and the second limiting portion, such that the circuit board is limited to be in the receiving space.

3. The fixing structure as claimed in claim 1, wherein the position limiting element and the base plate are integrally formed.

4. The fixing structure as claimed in claim 1, wherein a material of the position limiting element and the base plate is plastic.

5. The fixing structure as claimed in claim 1, wherein the circuit board is a flexible printed circuit board.

6. The fixing structure as claimed in claim 1, wherein the base plate further has a third side opposite to the first side, and the position limiting element further has a third limiting portion connecting the third side of the base plate.

7. The fixing structure as claimed in claim 1, further comprising a positioning pin disposed on the base plate, the circuit board having a positioning hole corresponding to the positioning pin.
